(19) United States
(12) Patent Application Publication
(10) Pub. No.: US 2026/0282459 A1
(43) Pub. Date: Sep. 17, 2026

(54) SEMICONDUCTOR TRANSISTOR MESA ISOLATION STRUCTURE AND METHOD OF FORMING THE SAME

(71) Applicant: Taiwan Semiconductor Manufacturing Company, Ltd., Hsinchu (TW)

(72) Inventors: Tzu-Wen Shih, Hsinchu (TW); Der-Ming Kuo, Hsinchu (TW); Ching-Heng Liu, Miaoli (TW); Shih-Hsiang Tai, New Taipei (TW)

(21) Appl. No.: 19/078,454

(22) Filed: Mar. 13, 2025

(51) Int. Cl. H10D 62/10; H10D 30/01; H10D 30/47; H10D 62/824; H10D 64/27

(52) U.S. Cl. CPC H10D 62/102; H10D 30/015; H10D 30/475; H10D 30/478; H10D 62/115; H10D 62/824; H10D 64/411

(57) ABSTRACT

A semiconductor transistor mesa isolation structure and method of forming the same including a mesa isolation structure located between a first gate and a second gate, the mesa isolation structure including sidewalls latitudinally offset from each of the first gate and the second gate, and the mesa isolation structure extending through an interior of a barrier layer of the semiconductor transistor, and the mesa isolation structure formed with a dielectric material.

### BACKGROUND

The following relates to semiconductor integrated circuits (ICs), IC fabrication processes, isolation structures for IC devices and (sub-)circuits, and the like.

For proper IC operation, constituent electronic components (e.g., single electronic devices, or sub-circuits of the IC) may be electrically isolated from one another to avoid deleterious interactions, including but not limited to, leakage currents. The following discloses semiconductor transistor mesa isolation structures, and methods of forming the same, with certain advantages as disclosed herein.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a of a semiconductor structure/integrated circuit (IC)/IC die including a mesa isolation structure according to an example embodiment of this disclosure, the mesa isolation structure having a structure (Embodiment 1) including sidewalls latitudinally offset from each of a first gate layer and second gate layer, and the mesa isolation structure extending entirely through the barrier layer structure and through a portion of an interior of a carrier channel layer structure.

FIG. 1B is a cross sectional view along line AA of the semiconductor structure/IC including a mesa isolation structure shown in FIG. 1A.

FIG. 1C is a top view of an area of the mesa isolation structure proximate to a gate metal and source metal according to the example embodiment of this disclosure shown in FIGS. 1A and 1B.

FIG. 2 is a cross sectional view of a semiconductor structure/integrated circuit (IC)/IC die along line AA of the semiconductor structure/IC shown in FIG. 1A, the semiconductor structure/integrated circuit (IC) including a mesa isolation structure according to an example embodiment of this disclosure, the mesa isolation structure having a partial mesa structure (Embodiment 2) including sidewalls latitudinally offset from each of a first gate layer and second gate layer, and the mesa isolation structure extending only within the entire depth of barrier layer structure.

FIG. 3 is a cross sectional view of a semiconductor structure/integrated circuit (IC)/IC die along line AA of the semiconductor structure/IC shown in FIG. 1A, the semiconductor structure/integrated circuit (IC) including a mesa isolation structure according to an example embodiment of this disclosure, the mesa isolation structure having a full mesa structure (Embodiment 3) including sidewalls latitudinally offset from each of a first gate layer and second gate layer, and the mesa isolation structure extending entirely through a depth or thickness of the barrier layer structure and carrier channel layer structure.

FIG. 4 is a cross sectional view of a semiconductor structure/integrated circuit (IC)/IC die along line AA of the semiconductor structure/IC shown in FIG. 1A, the semiconductor structure/integrated circuit (IC) including a mesa isolation structure according to an example embodiment of this disclosure, the mesa isolation structure having a mesa structure (Embodiment 4) including sidewalls latitudinally offset from each of a first gate layer and second gate layer, the mesa isolation structure including an isolation implant (ISO IMP) layer or region extending along the sidewalls and bottom of a mesa trench defining the mesa isolation structure, and the isolation implant (ISO IMP) process to form the isolation implanat layer or region is performed prior to etching the mesa trench.

FIG. 5 is a cross sectional view of a semiconductor structure/integrated circuit (IC)/IC die along line AA of the semiconductor structure/IC shown in FIG. 1A, the semiconductor structure/integrated circuit (IC) including a mesa isolation structure according to an example embodiment of this disclosure, the mesa isolation structure having a mesa structure (Embodiment 5) including sidewalls latitudinally offset from each of a first gate layer and second gate layer, and the mesa isolation structure including an isolation implant (ISO IMP) layer or region extending along the sidewalls and bottom of a mesa trench defining the mesa isolation structure, where the isolation implant (ISO IMP) process to form the isolation implant layer or region is performed after etching the mesa trench.

FIG. 6 is a cross sectional view of a semiconductor structure/integrated circuit (IC)/IC die along line AA of the semiconductor structure/IC shown in FIG. 1A, the semiconductor structure/integrated circuit (IC) including a mesa isolation structure according to an example embodiment of this disclosure, the mesa isolation structure having a mesa structure (Embodiment 6) including sidewalls latitudinally offset from each of a first gate layer and second gate layer, and the mesa isolation structure including a dielectric trench layer extending along the sidewalls and bottom of a mesa trench defining the mesa isolation structure, where the dielectric deposition process to form the dielectric trench layer is performed after etching the mesa trench.

FIG. 7 is a cross sectional view of a semiconductor structure/integrated circuit (IC)/IC die along line AA of the semiconductor structure/IC shown in FIG. 1A, the semiconductor structure/integrated circuit (IC) including a mesa isolation structure according to an example embodiment of this disclosure, the mesa isolation structure having a partial mesa structure (Embodiment 7) including sidewalls latitudinally offset from each of a first gate layer and second gate layer, and the mesa isolation structure sidewalls forming a reverse trapezoidal shaped mesa.

FIGS. 8A-8F show an example IC fabrication processing sequence (Embodiment 8) to form a semiconductor structure/integrated circuit (IC)/IC die including a mesa isolation structure including mesa trench sidewall ISO IMP treatment or dielectric film treatment according to an example embodiment of this disclosure.

FIG. 9A (Embodiment 9A) and 9B (Embodiment 9B) are flow charts of methods of forming a semiconductor structure/integrated circuit (IC)/IC die including a mesa isolation structure according to example embodiments of this disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

The term “substrate” herein generally refers to the bulk substrate on which various layers and device structures are formed.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “layer,” as used herein, may include a single layers or multiple layers.

The term “conductive feature,” as may be used herein refers to a metallization layer contact, patterned metallization layer contact, or other electrical metal contact.

The term “intermetal dielectric” (IMD) film or layer, as may be used herein, refers to a dielectric/insulation material(s) layer between two metal layers.

The term “interlayer dielectric” (ILD) layer, as may be used herein, refers to an insulating structure of material(s) placed between two conductive layers.

The term “line” and “metal line,” as may be used herein, is a conductive path that is created during the back end of line (BEOL) process and transmits electrical signals through a semiconductor chip's circuit pattern.

The term “orthogonal axis,” as used herein, refers to an axis substantially at 90 degrees relative to a longitudinal axis of a structure.

The term “oxide definition area”, or “active area” as used herein, refers to a specific region on a semiconductor wafer where the oxide layer is deliberately patterned to define the active area for transistors within an integrated circuit (IC), essentially outlining the boundaries of where the transistors will be built, separating them from inactive areas like isolation regions; this can be achieved through a process called “oxide definition” where the oxide layer is selectively removed in desired areas to create the active regions for transistors.

The term “mesa,” “mesa etch away,” “mesa etch structure,” and “mesa isolation structure,” as used herein, refer to an isolation mesa type structure oriented substantially orthogonal to a carrier channel or carrier channel layer.

Modem day integrated chips comprise millions or billions of semiconductor devices formed on a semiconductor substrate (e.g., silicon). Integrated chips (ICs) may use many different types of semiconductor devices, depending on an application of an IC.

To manufacture ICs and/or IC dies, a plurality of semiconductor chip regions are marked on a substrate by scribe lines between chip regions. The substrate goes through a variety of cleaning, layering, patterning, etching and doping steps to form integrated circuits. In some embodiments, the bulk substrate includes silicon or a compound semiconductor, such as GaAs, InP, Si/Ge, or SiC. Examples of such layers include dielectric layers, doped layers, polysilicon layers or conductive layers. Examples of device structures include transistors, resistors, and/or capacitors, which may be interconnected through an interconnect layer to additional integrated circuits. To reduce the area of the IC, the semiconductor devices may be formed in close proximity to one another. To prevent interference amongst the semiconductor devices, techniques and/or features for device isolation are incorporated into semiconductor devices and structures.

Among other things, DTI structures can provide electrical isolation amongst semiconductor devices to improve device performance without sacrificing a large area on the IC. In addition, isolation regions between specific active regions or areas of a device may be formed to prevent or minimize leakage current and enhance the performance of the device by improving by increasing the break down voltage (BV) performance of the device.

This disclosure, and the example embodiments described herein, relate to semiconductor transistor mesa isolation structures and methods of forming the same. Specifically, the semiconductor transistor structures described include a mesa isolation structure located between a first gate and a second gate of the transistor structure where the mesa isolation structure includes sidewalls latitudinally offset from each of the first gate and the second gate of the transistor structure. The mesa isolation structure extends through at least a portion of an interior of a barrier layer of the semiconductor transistor, and the mesa isolation structure is formed with a dielectric material.

The example embodiments described herein specifically relate to high electron mobility transistors (HEMT) and will be described with reference to HEMT structures. However, the use of the disclosed isolation mesa structures is not limited to HEMT structures, and can include other semiconductor transistor structures that include heterojunctions and/or heterojunction interfaces for carrier conduction.

Group III-nitride materials have a large bandgap compared to other semiconductor materials such as group III-arsenide materials. For example, gallium nitride (GaN) has a room temperature bandgap of around 3.4 eV, compared with a bandgap of around 1.42 eV for gallium arsenide (GaAs). The large bandgap makes group III-nitride-based devices well suited for applications calling for high power and/or operating at high temperature. For example, GaN-based devices find application in electronic devices and systems such as fast chargers, mobile switchers, integrated circuit (IC) drivers, on-board chargers (OBC), power for server/data centers, electric vehicles, and so forth, by way of some nonlimiting illustrative examples.

One type of group III-nitride device used in such tasks is the p-GaN high electron mobility transistor (HEMT). In this device, a two-dimensional electron gas (2DEG) is formed at a heterointerface between a ternary aluminum gallium nitride (AlₓGa₁₋ₓN) layer and a gallium nitride (GaN) layer. The subscript x in AlₓGa₁₋ₓN denotes the Al fraction, where x=0 corresponds to GaN and x=1 corresponds to AlN. For notational convenience herein, AlₓGa₁₋ₓN is sometimes written without the subscripts as AlGaN. The 2DEG is formed due to the piezoelectric effect, and the AlGaN layer is thin enough to be coherently strained, i.e., the in-plane lattice constant of the thin AlGaN layer is strained to match the in-plane lattice constant of the thicker GaN layer. A p-type GaN layer (p-GaN layer) serves as the gate of the HEMT. While the illustrative embodiments employ a p-GaN gate, in other HEMT designs the gate may be n-type, i.e., an n-type GaN or n-GaN gate.

A problem can arise in such devices, in that the leakage current when the device is off (i.e., in the nonconductive state) can be higher than desired. In other words, the electric current I_{S,off} which is the source-to-drain current in the (nominally) nonconductive state is higher than desired.

Disclosed herein are improved electronic structures and devices in which the leakage current is blocked and the BV of the device is improved, i.e., increased. Specifically, disclosed is a mesa etch structure (e.g., partial etch GaN epitaxial layer through a AlGaN/GaN interface for cut off of e−) on a GaN HEMT epitaxial layer to replace current structures and methods that use isolation (ISO) implant methods to control BV and reduce or eliminate leakage current. Using an isolation mesa structure that includes etching one or both of a HEMT barrier layer and conductive layer structure, e.g., GaN epitaxial layer, to block the electron path from the source to the drain proximate the gate contact region, thereby preventing current leakage.

Stated another way, the electrons in a GaN HEMT conductor on the surface of AlGaN and GaN. By using a mesa etch, as disclosed herein, to cut away the structure the electrons will no longer conduct in this area, thereby preventing electron accumulation during operation of the device/structure. Previous methods and structures used implant isolation as a techniques to destroy the structure, however the use of implant isolation techniques has the risk of generating electrons.

Applications of the disclosed transistor structures/devices/ICs, etc. include, but are not limited to, GaN HEMT high, low voltage device structures, e.g. D-HEMT, D-MOSFET, E-HEMT, operating at voltages of 30V, 40V, 80V, 100V, 650V, 1200V, etc., where the operational voltages can depend on one or more of: (1) epitaxial structure, (2) device gate-drain length and (3) field plate design. Example products and/or device applications include, but are not limited to, GaN power device applications; fast chargers; data center devices; civil radar; OBCs (on-board charger) DC/DC conversion; electric vehicle charging off-board; photovoltaic inverter . . . etc.

Current ISO implant methods for controlling leakage current tend to damage the AlGaN/GaN crystal structure, and the crystal damage acts as a trap center for e− migration. Furthermore, e− migration can also be affected by dielectric screens/thickness and isolation dose, energy and depth. The disclosed mesa isolation structures replace the current ISO implant methods for controlling leakage current by replacing the current ISO implant region with a mesa isolation structure formed using a mesa etch process to cut-off AlGaN/GaN Piezoelectric effect generated e− and the e− transport path.

According to some embodiments, the structures disclosed herein include, but are not limited to, the following.

Embodiment 1 (Structure): A mesa isolation structure etch depth through an entire top heterojunction semiconductor layer (AlGaN) and partially through a bottom heterojunction semiconductor layer (GaN), thereby mitigating or eliminating the AlGaN/GaN piezoelectric effect behavior at the heterojunction interface.

Embodiment 2 (Structure): A mesa isolation structure etch depth only through the top heterojunction semiconductor layer (AlGaN) and NOT through the bottom heterojunction semiconductor layer (GaN).

Embodiment 3 (Structure): A mesa isolation structure etch depth through the entire top heterojunction semiconductor layer (AlGaN) and through the entire bottom heterojunction semiconductor layer (GaN), thereby mitigating or eliminating the AlGaN/GaN piezoelectric effect behavior at the heterojunction interface.

Embodiment 4 (Structure): A mesa isolation structure etch depth through the entire top heterojunction semiconductor layer (AlGaN) and partially through the bottom heterojunction semiconductor layer (GaN). Optionally, also included is an ISO implant layer or region, i.e., channel block layer, between the mesa and the heterojunction semiconductor layers which is formed by performing an ISO implant process initially, then etching the ISO implant region to create a trench for the mesa isolation structure. It is to be understood that the ISO implant layer of this embodiment can also be used with other embodiments disclosed herein, e.g., partial and full mesa isolation structures, which do not illustrate a channel block layer within the trench of the mesa isolation structure.

Embodiment 5 (Structure): A mesa isolation structure etch depth through the entire top heterojunction semiconductor layer (AlGaN) and partially through the bottom heterojunction semiconductor layer (GaN). Optionally, also included is an ISO implant process that includes initially etching the heterojunction semiconductor layers to form a mesa trench\ then performing an ISO implant process to create a ISO implant layer/channel block layer or region within the sides of the mesa isolation structure trench. It is to be understood that the ISO implant layer of this embodiment can also be used with other embodiments disclosed herein, e.g., partial and full mesa isolation structures, which do not illustrate a channel block layer within the trench of the mesa isolation structure.

Embodiment 6 (Structure): A mesa isolation structure etch depth through the entire top heterojunction semiconductor layer (AlGaN) and partially through the bottom heterojunction semiconductor layer (GaN). Optionally, also included is a dielectric film between the mesa and the heterojunction semiconductor layers. The dielectric film acts as a channel block layer. It is to be understood that the dielectric layer of this embodiment can also be used with other embodiments disclosed herein, e.g., partial and full mesa isolation structures, which do not illustrate a channel block layer within the trench of the mesa isolation structure.

Embodiment 7 (Structure): A mesa isolation structure etch depth through the entire top heterojunction semiconductor layer (AlGaN) and partially through the bottom heterojunction semiconductor layer (GaN), the mesa etch having a reverse trapezoidal shape. It is to be understood that the reverse trapezoidal shaped mesa isolation structure can also be used with other embodiments disclosed herein, e.g., partial and full mesa isolation structures.

Embodiment 8 (Fabrication Processing Sequence): IC fabrication processing sequence to form a semiconductor structure/integrated circuit (IC)/IC die including a mesa isolation structure including optional mesa trench sidewall ISO implant treatment or dielectric film treatment.

Embodiments 9A and 9B: Method and/or processing to form various stages of Embodiments 1-7.

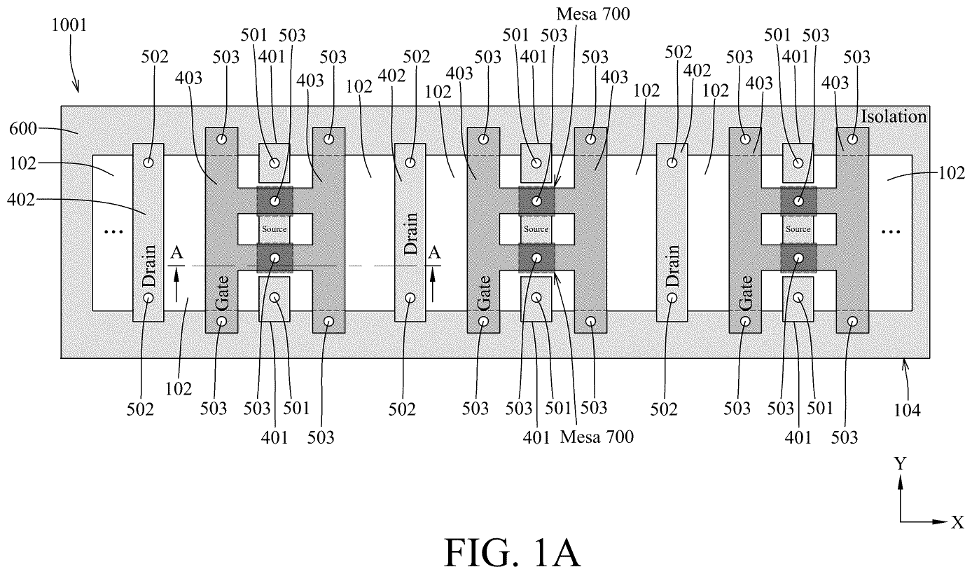

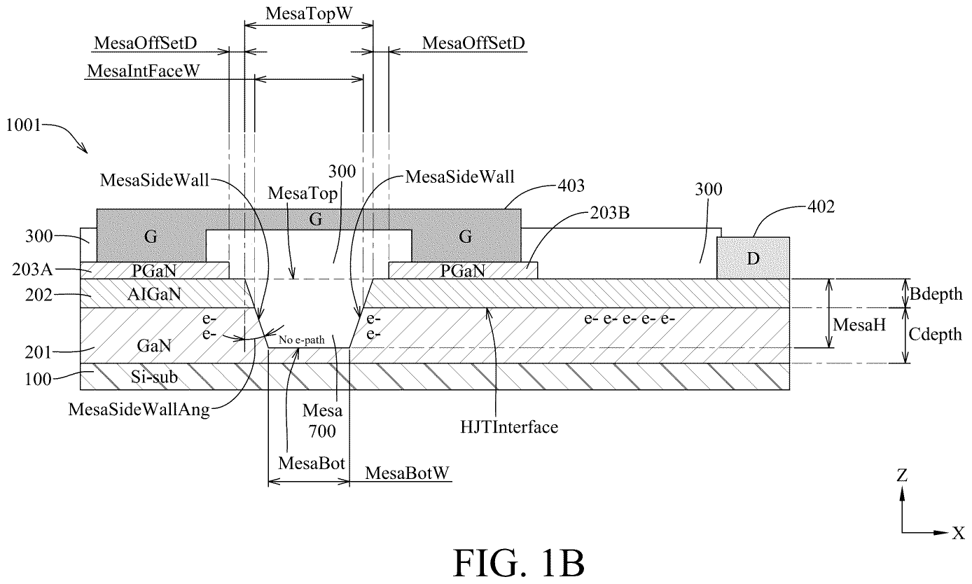

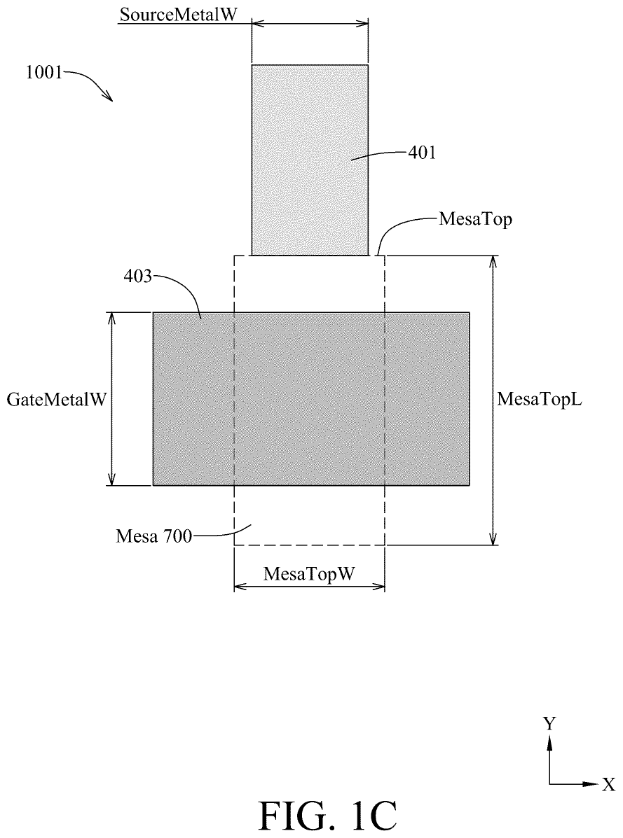

With reference to FIGS. 1A-1C, FIG. 1A shows a top view of a semiconductor structure/integrated circuit (IC)/IC die including a mesa isolation structure according to an example embodiment of this disclosure, the mesa isolation structure having a structure (Embodiment 1) including sidewalls latitudinally offset from each of a first gate layer and second gate layer, and the mesa isolation structure extending entirely through the barrier layer structure and through a portion of an interior of a carrier channel layer structure; FIG. 1B shows a cross sectional view along line AA of the semiconductor structure/IC including a mesa isolation structure shown in FIG. 1A; and FIG. 1C shows a top view of an area of the mesa isolation structure proximate to a gate metal and source metal according to the example embodiment of this disclosure shown in FIGS. 1A and 1B.

As shown, this embodiment includes a normally off HEMS transistor structure (e.g., E-HEMT GaN device), where a 2DEG (two-dimensional electron gas) conductive channel, shown as e− is proximate a GaN/AlGaN heterojunction. It is to be understood that while the descriptions that follow specifically describe a E-HEMT GaN stricture or device, other HEMT or transistor structures are within the scope of this disclosure and can include D-HEMT GaN devices or other transistor structures including a heterojunction that provides a 2DEG (two-dimensional electron gas) conductive channel.

In operation, the E-HEMT transistor device shown in FIGS. 1A-1C is turned ON by applying a gate voltage to gates 203A and 203B via gate metal 403, the gate voltage controlling the S/D (source/drain) current flow from source metals 401 to drain metals 402, via source contacts 501 and drain contacts 502, respectively. As will be further described herein, a mesa isolation structure 700 provides a cut off to mitigate, block or eliminate any leakage current resulting from the piezoelectric effect generated carrier conduction channel (e−) at the heterojunction interface HJTInterface underneath the gate metal 403 portion that extends over the mesa isolation structure 700. This portion of the gate metal 403 acts as a common gate metal connection from gate 203A to 203B.

As shown in FIG. 1A, the HEMT transistor structure/device/IC/die 1001 active area 102 includes a plurality of bridged transistors where a common source/source metal 401 is operatively associated with two independent drains and gates. The transistor structure also includes an isolation region 600, e.g., isolation implant region, which encircles or surrounds the HEMT transistors, and provides an area for routing of the source metals 401, drain metals 402 and gate metals 403, and terminus points for gate metal contacts 503. Scribe line 104 is used during dicing or sawing of a wafer (not shown) to segment the wafer into a plurality of the HEMT transistor structures/device/ICs/dies 1001 shown. While the transistor structure shown in FIG. 1A includes three bridged HEMT structures, which are operatively connected to effectively provide a single HEMT structure according to an example embodiment, the transistor structure can include any number of HEMT transistor structures, such as, but not limited to 4, 5, 6, 7, etc.

With reference to FIG. 1B, shown is a cross sectional view along line AA to further illustrate and describe details of one of a plurality of HEMT structures/device as shown in FIG. 1A, each HEMT structures/device including a mesa isolation structure a disclosed herein. As shown, the HEMT structure includes a substrate 100, e.g., Si, a channel layer structure 201, e.g., GaN, a barrier layer 202, e.g., AlGaN, gates 203A and 203B, e.g., PGaN, gate metal 403 and drain metal 402. A source region/source metal 401 is not shown in FIG. 1B, and is located in front or behind of FIG. 1B, as shown in FIG. 1A.

The heterojunction interface HJTInterface located at the interface or junction of channel layer 201 and barrier layer 202 provides a conductive channel for the operation of the device, created by the piezoelectric effect resulting from the epitaxial growth of the channel layer 201 and barrier layer 202. As shown by the absence of e− underneath the gates 203A and 203B, the p doping of the gates provides a normal OFF operation of the HEMT transistor device. To mitigate any leakage current associated with the gate connection area, the mesa isolation structure 700 is formed to block the conductive channel at the HJT interface HJTInterface. In addition, the mesa isolation structure 700, and the methods of forming the same disclosed herein, eliminate any e− trapping that can occur at the bottom of the mesa isolation structure, where current methods of forming an isolation channel block region including merely an ISO implant block region without the etched mesa isolation structure 700, suffer from the generation of an e− trap at the bottom of the current ISO implant block region which create an e− path and degrade the BV and leakage current performance of the transistor device or structure.

The mesa isolation structure 700 is formed by etching a trench at least entirely through the barrier layer 202 to the HJT interface HJTInterface, thereby acting as a conductive channel block where the 2DEG is present. In addition, a dielectric layer/material 300, e.g., SiO₂, SiN, AlN, Al₂O₃, etc.) is deposited to fill the mesa trench area bounded by mesa sidewalls MesaSideWall extending to a bottom MesaBot of the etched trench of the mesa isolation structure 700. While the mesa isolation structure 700 shown in FIG. 1B includes a mesa isolation structure extending through the barrier layer 202 into the interior of the channel layer structure 201, it is to be understood that other embodiments, as will be described herein, include a mesa isolation structure 700 that 1) only extend through the barrier layer to the HJT interface HJTInterface, and 2) extend entirely through the barrier layer 202, through the HJT interface HJTInterface, and through the channel layer structure 201 to the substrate 100.

Referring to FIGS. 1B and 1C, features of the mesa isolation structure include the following:
A mesa sidewall angle or taper MesaSideWallAngle from about 30 degrees to about 60 degrees, the mesa sidewall MesaSideWall extending from a mesa top MesaTop to a bottom MesaBot of the mesa isolation structure 700.
A mesa top width MesaTopW from about 1 um to about 30 um.
A mesa bottom width MesaBotW from about 1 um to about 30 um.
A mesa height MesaH from about 1 nm to about 10 um.
A mesa top length MesaTopL from about 1 um to about 100 um.
A mesa offset distance MesaOffSetD from the adjacent gates 203A AND 203B from about 0.1 um to about 1 um; MesaOffSetD greater than 0, where the gates 203A and 203B are not in contact with the mesa isolation structure 700, the mesa isolation structure 700 is at an elevational level below the gates 203A and 203B, and a top of the mesa isolation structure MesaTop is proximate the first and second gate layers 203A and 203B.
A mesa HJT interface width MesaIntFaceW from about 1 um to about 30 um.
A gate metal width GateMetalW from about 1 um to about 100 um.
A source metal width SourceMetalW from about 1 um to about 30 um.
A barrier layer structure width Bdepth from about 1 nm to about 40 nm.
Additional dimensional relationships include 1) MesaTopW is greater than SourceMetalW; 2) MesaTopL is greater than GateMetalW; and 3) MesaH is greater than or equal to a barrier layer thickness or depth Bdepth, and can extend a distance Cdepth through the channel layer structure 201.

Regarding the source metal 401 structures, as shown the source metals 401 are segmented or slotted to accommodate the gate metal 403 and gate metal connection contacts 503.

Regarding the Mesa Isolation Structure, according to the example embodiment shown in FIGS. 1A, 1B and 1C, MesaTopW is greater than MesaBotW, however, as will be further described below with reference to other figures, MesaTopW can be less than MesaBotW.

Regarding the shape of the mesa isolation structure 700, specifically the mesa isolation structure top MesaTop, the embodiment shown in FIGS. 1A-1C includes a MesaTop shaped in a rectangle, however alternative shapes include, but are not limited to, square and polygonal.

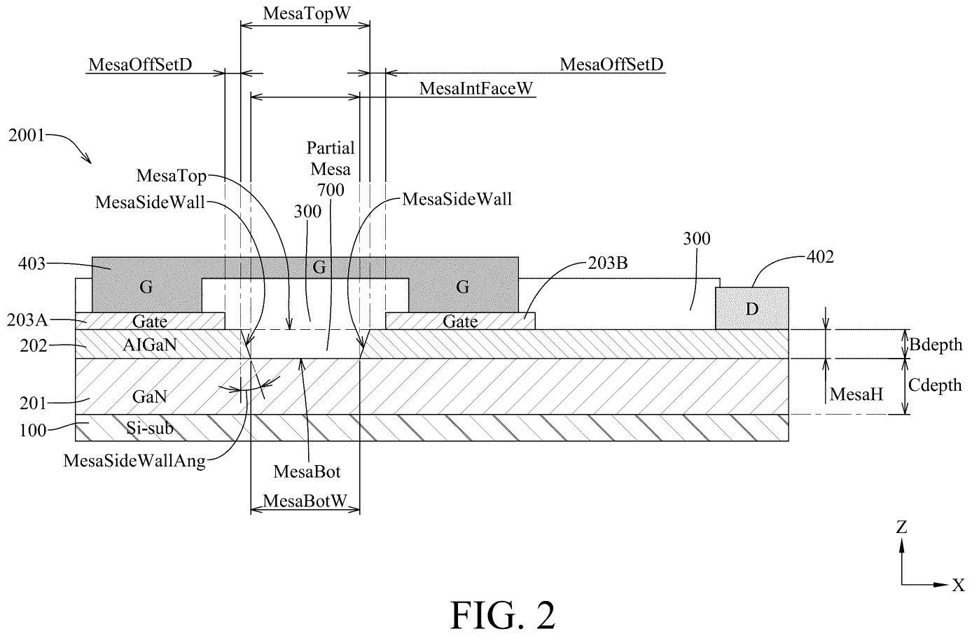

With reference to FIG. 2, shown is a cross sectional view of another example semiconductor structure/integrated circuit (IC)/IC die 2001 along line AA of the semiconductor structure/IC shown in FIG. 1A, the semiconductor structure/integrated circuit (IC) including a mesa isolation structure 700 according to an example embodiment of this disclosure, the mesa isolation structure having a partial mesa structure (Embodiment 2) including sidewalls MesaSideWall latitudinally offset from each of a first gate layer 203A and second gate layer 203B, and the mesa isolation structure 700 extending a depth MesaH entirely through the interior of the barrier layer structure 202.

While this embodiment provides an improvement to the current ISO implant methods for mitigating leakage current, there is some risk of leakage current. Further improvements in performance are obtained by extending the mesa isolation structure into the channel layer structure 201.

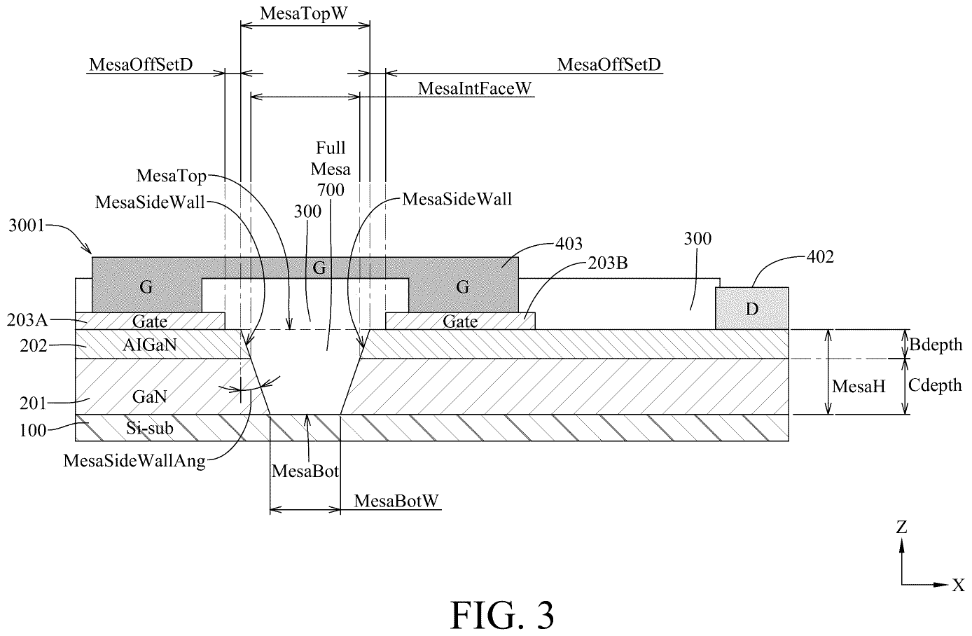

With reference to FIG. 3, shown is a cross sectional view of another example semiconductor structure/integrated circuit (IC)/IC die 3001 along line AA of the semiconductor structure/IC shown in FIG. 1A, the semiconductor structure/integrated circuit (IC) including a mesa isolation structure 700 according to an example embodiment of this disclosure, the mesa isolation structure having a full mesa structure (Embodiment 3) including sidewalls MesaSideWall latitudinally offset from each of a first gate layer 203A and second gate layer 203B, and the mesa isolation structure 700 extending entirely through a depth or thickness Bdepth of the barrier layer structure and entirely through a depth or thickness Cdepth of the carrier channel layer structure.

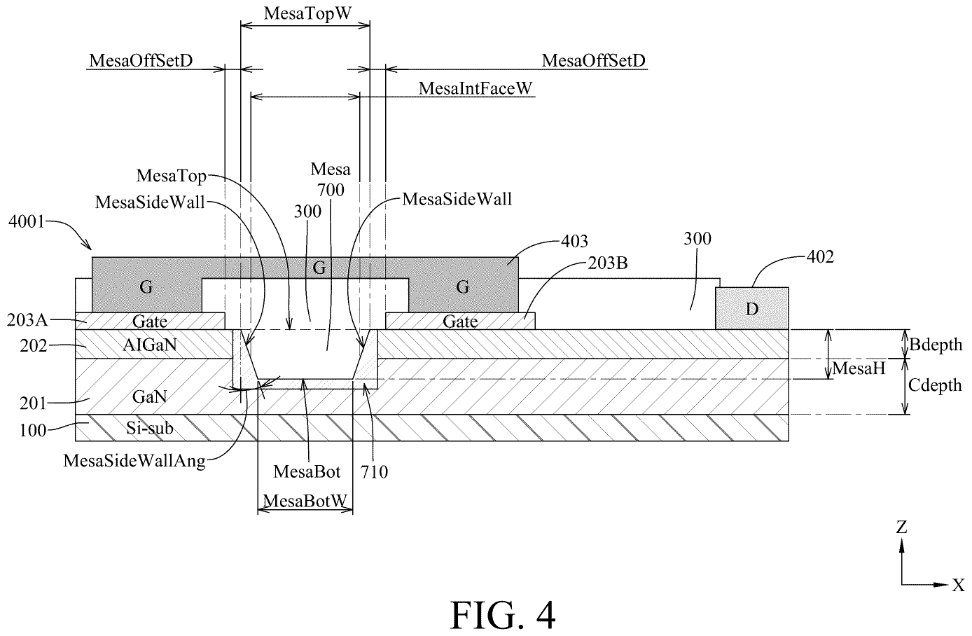

With reference to FIG. 4, shown is a cross sectional view of another example semiconductor structure/integrated circuit (IC)/IC die 4001 along line AA of the semiconductor structure/IC shown in FIG. 1A, the semiconductor structure/integrated circuit (IC) including a mesa isolation structure 700 according to an example embodiment of this disclosure, the mesa isolation structure 700 having a mesa structure (Embodiment 4) including sidewalls MesaSideWall latitudinally offset from each of a first gate layer 203A and second gate layer 203B, and the mesa isolation structure 700 including an isolation implant (ISO IMP) layer or region 710 extending along the sidewalls MesaSideWall and bottom MesaBot of a mesa trench region defining the mesa isolation structure 700.

According to this embodiment, an isolation implant (ISO IMP) process is used to form the isolation implant layer or region 710 prior to etching the channel layer structure 201 and barrier layer structure 202 to form a mesa trench for defining the mesa isolation structure 700. The isolation implant layer or region 710 functions to isolate the mesa isolation structure 700 dielectric filler 300, i.e., passivation cap layer, from the neighboring channel layer structure 201 and barrier layer structure 202.

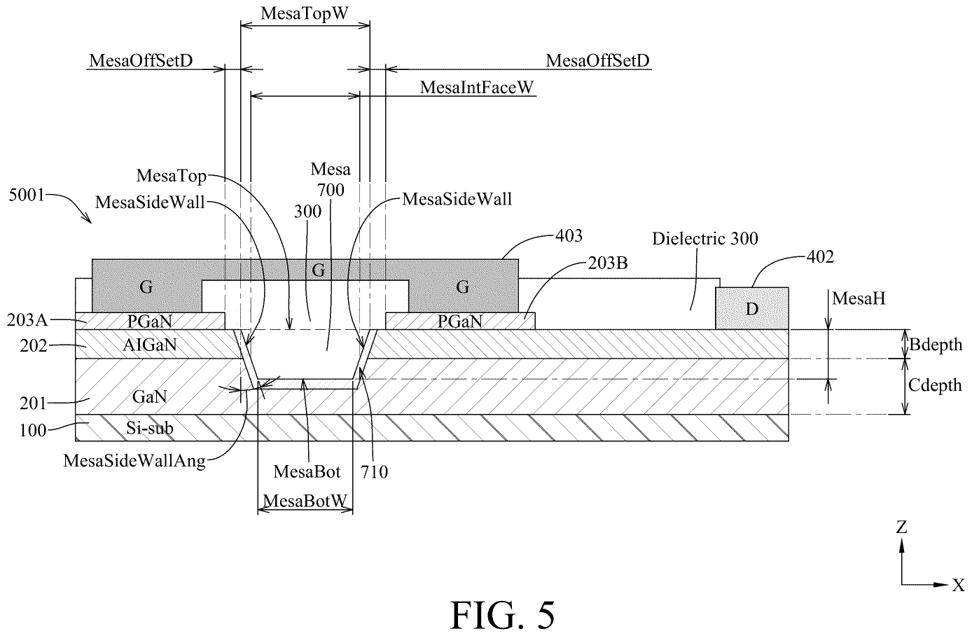

With reference to FIG. 5, shown is a cross sectional view of another example semiconductor structure/integrated circuit (IC)/IC die 5001 along line AA of the semiconductor structure/IC shown in FIG. 1A, the semiconductor structure/integrated circuit (IC) including a mesa isolation structure 700 according to an example embodiment of this disclosure, the mesa isolation structure 700 having a mesa structure (Embodiment 5) including sidewalls MesaSideWall latitudinally offset from each of a first gate layer 203A and second gate layer 203B, and the mesa isolation structure 700 including an isolation implant (ISO IMP) layer or region 710 extending along the sidewalls and bottom of a mesa trench defining the mesa isolation structure 700, where the isolation implant (ISO IMP) process to form the ISO IMP layer or region 710 is performed after etching the mesa trench.

According to this embodiment, an isolation implant (ISO IMP) process is used to form the isolation implant layer or region 710 after etching the channel layer structure 201 and barrier layer structure 202 to form a mesa trench for defining the mesa isolation structure 700. As with Embodiment 4, the isolation implant layer or region 710 functions to isolate the mesa isolation structure 700 dielectric filler 300, i.e., passivation cap layer, from the neighboring channel layer structure 201 and barrier layer structure 202.

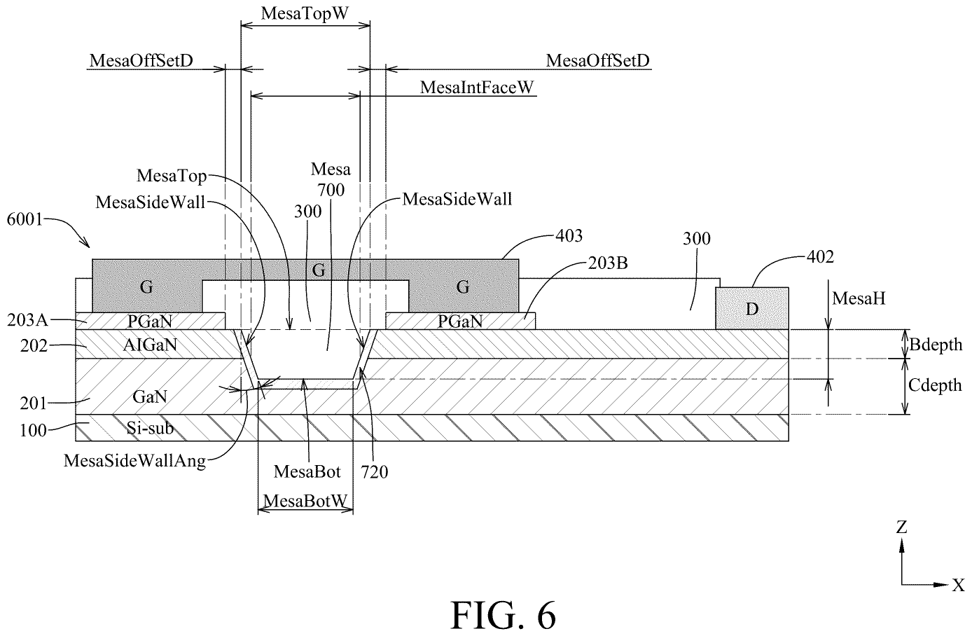

With reference to FIG. 6, shown is a cross sectional view of another example semiconductor structure/integrated circuit (IC)/IC die 6001 along line AA of the semiconductor structure/IC shown in FIG. 1A, the semiconductor structure/integrated circuit (IC) including a mesa isolation structure 700 according to an example embodiment of this disclosure, the mesa isolation structure 700 having a mesa structure (Embodiment 6) including sidewalls MesaSideWall latitudinally offset from each of a first gate layer 203A and second gate layer 203B, and the mesa isolation structure including a dielectric trench layer 720 extending along the sidewalls MesaSideWall and bottom MesaBot of a mesa trench defining the mesa isolation structure 700. The dielectric deposition process to form the dielectric trench layer 720 is performed after etching the mesa trench.

The function and purpose of the dielectric trench layer 720 is to recover dangling Ga—N's Ga— bond's “N” position generated during the mesa etching process and thereby mitigate leakage current lower leakage. Options for the dielectric layer 720 include 1) dielectric film material types with N, for example AlN, Si₃N_{4,} etc. and 2) a high k dielectric film material type, for example Al₂O₃, TiO₂, Si₃N₄ ZrO₂, HfO₂. . . etc., which use interfacial dipoles to trap electrons to lower or mitigate e− transport leakage.

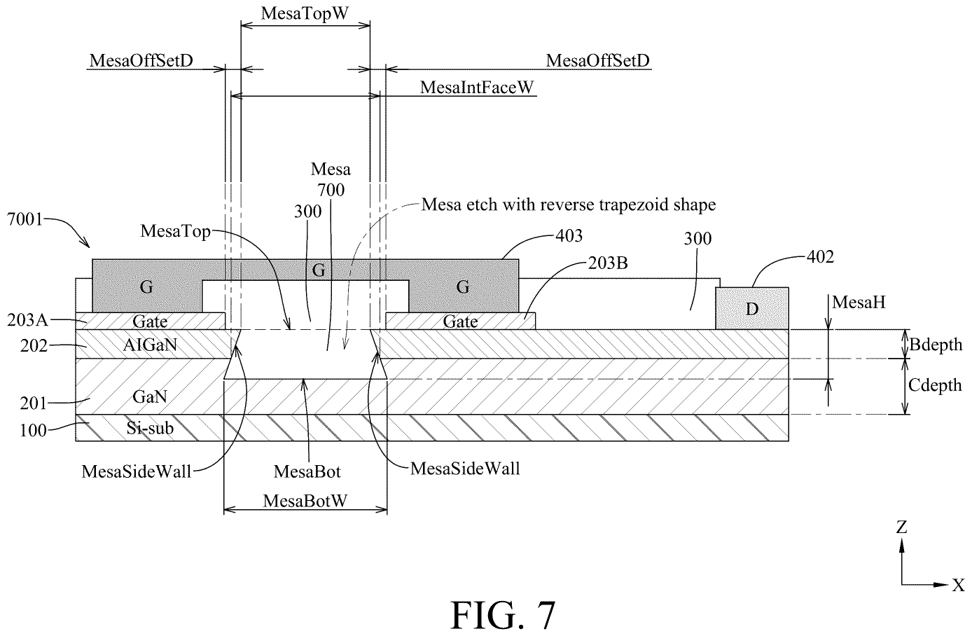

With reference to FIG. 7, shown is a cross sectional view of another example semiconductor structure/integrated circuit (IC)/IC die 7001 along line AA of the semiconductor structure/IC shown in FIG. 1A, the semiconductor structure/integrated circuit (IC) including a mesa isolation structure according to an example embodiment of this disclosure, the mesa isolation structure 700 having a partial mesa structure (Embodiment 7) including etched sidewalls MesaSideWall latitudinally offset from each of a first gate layer 203A and second gate layer, and the mesa isolation structure sidewalls MesaSideWall forming a reverse trapezoidal shaped mesa, where MesaBotW is greater than MesaTopW.

The function and purpose of the reverse trapezoidal shaped mesa 700 is to provide a relatively wide mesa bottom width MesaBotW which is deep within the channel layer structure 201 and further way from the AlGaN to GaN interface HJTInterface for further mitigating leakage current e−. Possible techniques for etching the reverse trapezoidal mesa structure include plasma etching using an antenna electric field for horizontal etching.

According to an example embodiment, the Embodiments 1, 2, 3, 4, 5, 6, and 7, are formed on one or more wafers made of a semiconducting material, where the semiconductor structures including mesa isolation structures are built or formed thereon by conventional semiconductor fabrication techniques, including but not limited to photolithographic techniques such as applying a pattern/structure in a given layer by applying a photoresist layer, patterning the photoresist layer, developing the photoresist layer, and then etching, followed by planarizing and cleaning. While the specific semiconductor fabrication processes required to form the disclosed embodiments shown and described are not the focus of this disclosure, for completeness a general description of the semiconductor fabrication processes follows.

The semiconductor substrate materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl- 2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

Dielectric structures or layers of the devices disclosed can be made from any suitable combination of dielectric materials. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

Any electrically conductive material, discussed herein may generally be any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

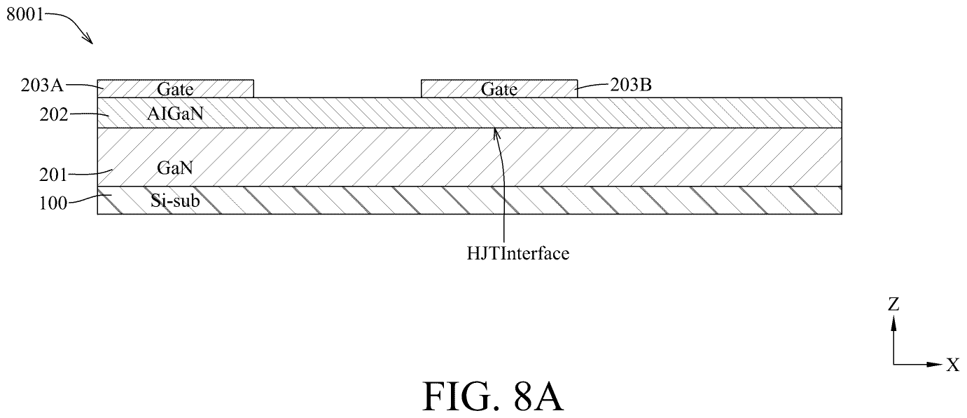

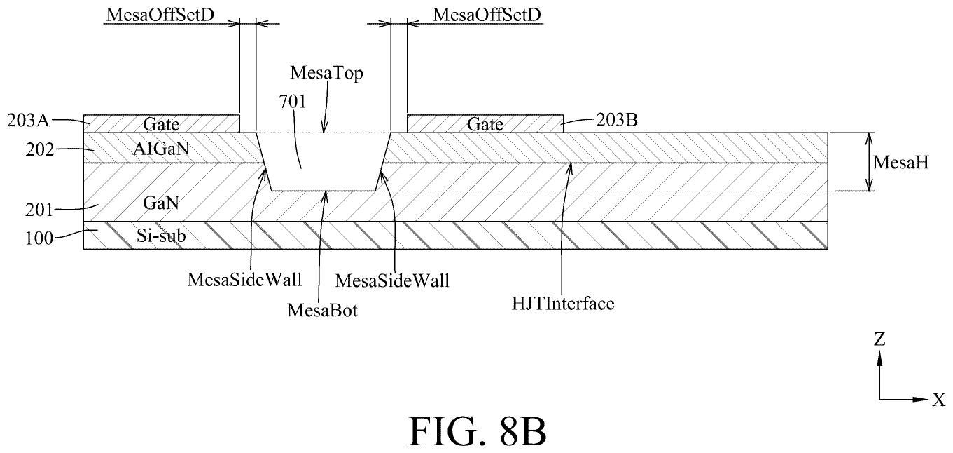

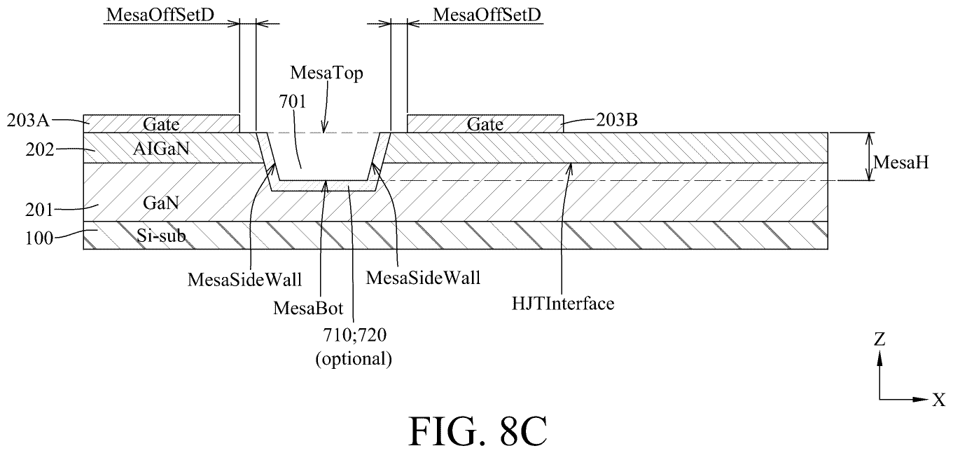

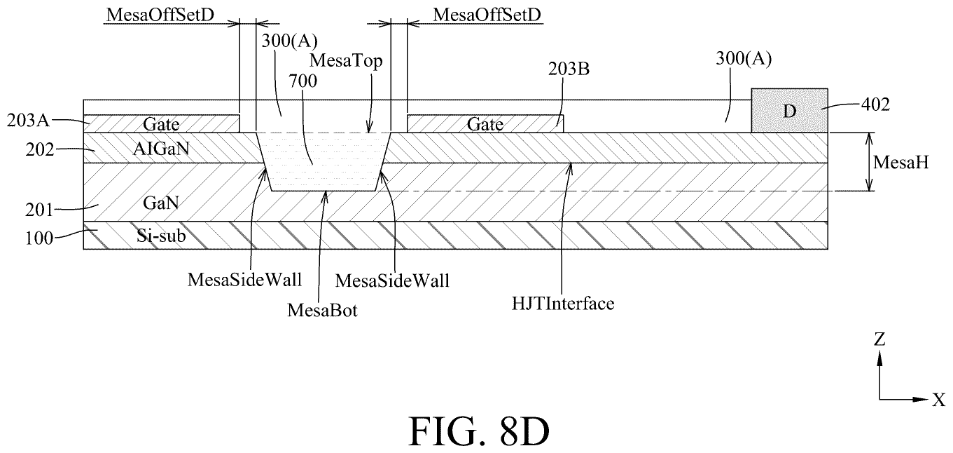

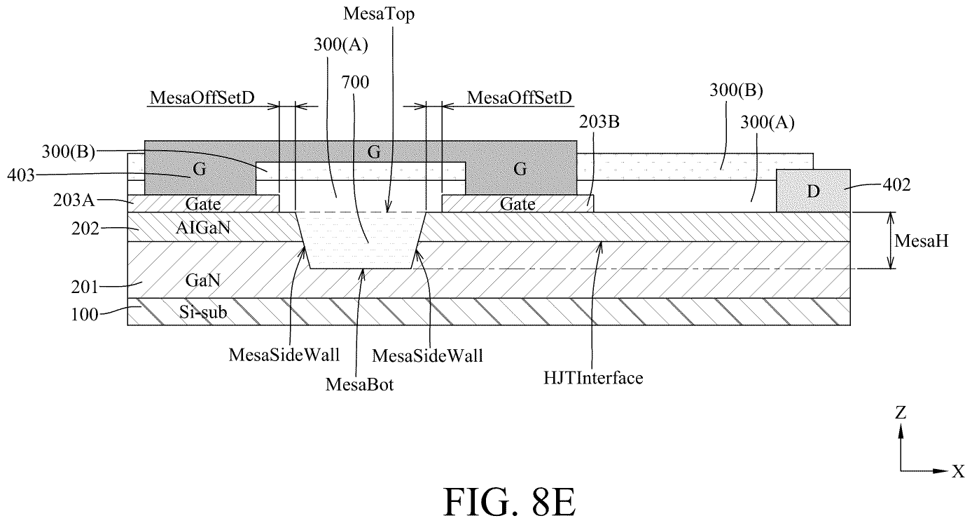

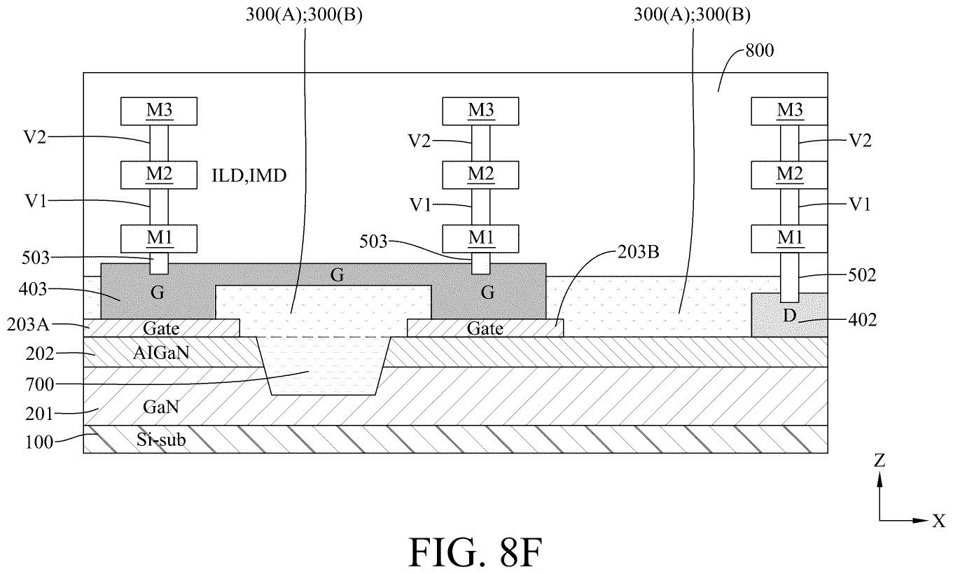

With reference to FIGS. 8A-8F, shown are various fabrication steps associated with the fabrication of an IC structure according to an example embodiment 8001 of the present disclosure.

With reference to FIG. 8A, shown is an initial stage or state of the HEMT structure, where an epitaxial process is performed to 1) grow a GaN channel layer structure 201 on a Si substrate 100; 2) epitaxially growing a AlGaN barrier layer structure 202 on the GaN channel layer structure 201; and 3) epitaxially growing a PGaN layer and using a photolithographic process to define gates 203A and 203B.

With reference to FIG. 8B, shown is a next stage of fabrication where a mesa trench 701 is etched through the AlGaN/GaN HJT interface to cut off the 2DEG conduction channel underneath the gate metal connection region (not shown; refer to 403 and 503 in FIGS. 1A and 1B).

With reference to FIG. 8C (Optional; Embodiments 5 and 6), shown is a next stage of fabrication where the sidewalls MesaSideWall of the mesa trench 701 are treated with a dielectric film, e.g., dielectric film deposition process, to provide e− recovery, etc. as previously described.

With reference to FIG. 8D, shown is a next stage of fabrication where dielectric layer(s) 300(A) are deposited over the mesa trench 701, gates 203A and 203B, and exposed areas of the barrier layer structure 202. In addition, source metals 401 (shown in FIG. 1A) and drain metals 402 are defined using a photolithographic process to etch the dielectric layer(s) 300(A) and deposition of the source and drain metal lines 401 and 402, respectively. According to an example embodiment, example dielectric layer(s) 300(A) material includes, but is not limited to, SiO₂, SiN, AlN, Al₂O, etc.)

With reference to FIG. 8E, shown is a next stage of fabrication where a photolithographic etching process us used to define gates 203A and 203B, an optional second dielectric layer(s) 300(B) is deposited to provide additional isolation/BV performance of the device, depending on the operating environmental conditions or operating voltages. According to an example embodiment, example dielectric layer(s) 300(B) material includes, but is not limited to, SiO₂, SiN, AlN, Al₂O, etc.), which can include dielectric material used for dielectric layer(s) 300(A) or be different.

With reference to FIG. 8F, shown is a next stage of fabrication where additional photolithographic/etching/deposition, etc. processing forms interlayer dielectric layers ILD, intermetal dielectric layers IMD, source contacts 501 (not shown), drain contacts 502, gate contacts 503, metallization layers M1, M2 and M3, and vias V1, V2 and V3.

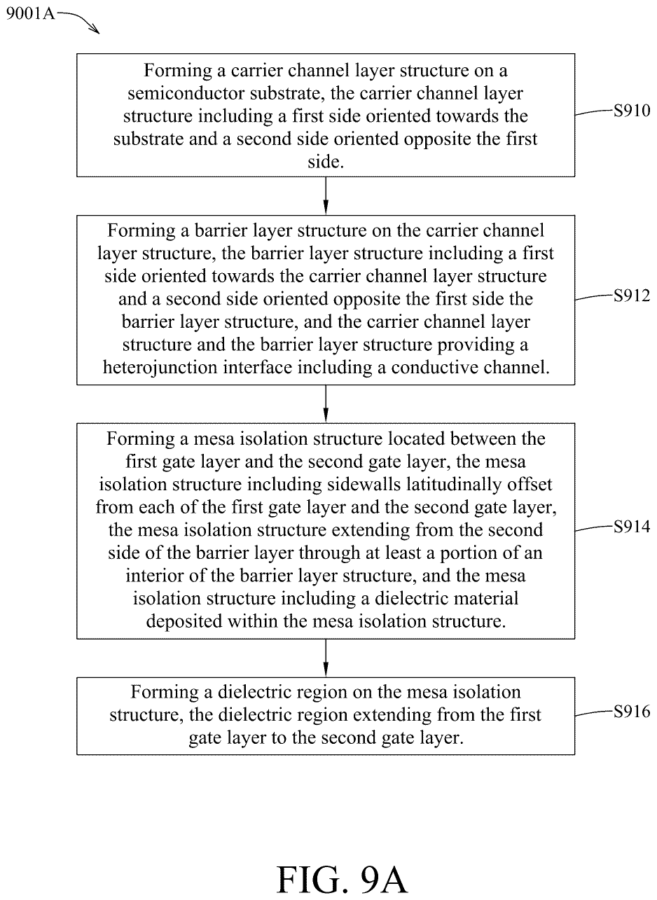

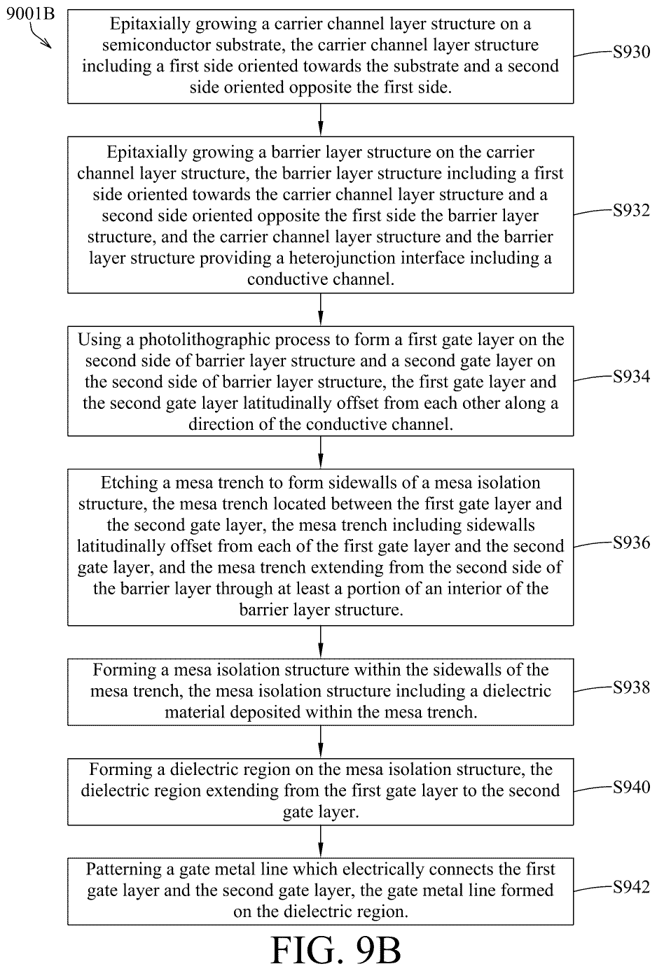

With reference to FIG. 9A, shown are various fabrication steps associated with the fabrication of an IC structure according to an example embodiment 9001A (Embodiment 9A) of the present disclosure.

At step S910, the method forms a carrier channel layer structure on a semiconductor substrate, the carrier channel layer structure including a first side oriented towards the substrate and a second side oriented opposite the first side.

At step S912, the method forms a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a conductive channel.

At step S914, the method forms a mesa isolation structure located between the first gate layer and the second gate layer, the mesa isolation structure including sidewalls latitudinally offset from each of the first gate layer and the second gate layer, the mesa isolation structure extending from the second side of the barrier layer through at least a portion of an interior of the barrier layer structure, and the mesa isolation structure including a dielectric material deposited within the mesa isolation structure.

At step S916, the method forms a dielectric region on the mesa isolation structure, the dielectric region extending from the first gate layer to the second gate layer.

With reference to FIG. 9B, illustrated are various fabrication steps associated with the fabrication of an IC structure according to another example embodiment 9001B (Embodiment 9B) of the present disclosure.

At step S930, the method epitaxially grows a carrier channel layer structure on a semiconductor substrate, the carrier channel layer structure including a first side oriented towards the substrate and a second side oriented opposite the first side.

At step S932, the method epitaxially grows a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a conductive channel.

At step S934, the method performs a photolithographic process to form a first gate layer on the second side of barrier layer structure and a second gate layer on the second side of barrier layer structure, the first gate layer and the second gate layer latitudinally offset from each other along a direction of the conductive channel.

At step S936, the method etches a mesa trench to form sidewalls of a mesa isolation structure, the mesa trench located between the first gate layer and the second gate layer, the mesa trench including sidewalls latitudinally offset from each of the first gate layer and the second gate layer, and the mesa trench extending from the second side of the barrier layer through at least a portion of an interior of the barrier layer structure.

At step S938, the method forms a mesa isolation structure within the sidewalls of the mesa trench, the mesa isolation structure including a dielectric material deposited within the mesa trench.

At step S940, the method forms a dielectric region on the mesa isolation structure, the dielectric region extending from the first gate layer to the second gate layer.

At step S942, the method patterns a gate metal line which electrically connects the first gate layer and the second gate layer, the gate metal line formed on the dielectric region.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the disclosed mesa isolation structures, and methods of forming the same, provide for an improved BV and leakage current performance of an IC device including, but not limited to, a HEMT, whereby the overall BV and leakage current performance of the device is improved.

In the following, some further embodiments are described.

In a nonlimiting illustrative embodiment, a method of forming of forming a semiconductor transistor structure comprising: forming a carrier channel layer structure on a semiconductor substrate, the carrier channel layer structure including a first side oriented towards the substrate and a second side oriented opposite the first side; forming a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a 2 dimensional electron gas (2DEG) conductive channel; forming a first gate layer on the second side of barrier layer structure and a second gate layer on the second side of barrier layer structure, the first gate layer and the second gate layer latitudinally offset from each other along a direction of the conductive channel; forming a mesa isolation structure located between the first gate layer and the second gate layer, the mesa isolation structure including sidewalls latitudinally offset from each of the first gate layer and the second gate layer, the mesa isolation structure extending from the second side of the barrier layer through an interior of the barrier layer structure, and the mesa isolation structure formed with a dielectric material; and forming a dielectric region on the mesa isolation structure, the dielectric region extending from the first gate layer to the second gate layer.

In another nonlimiting illustrative embodiment, a semiconductor device comprising: a carrier channel layer structure on a semiconductor substrate, the carrier channel layer structure including a first side oriented towards the substrate and a second side oriented opposite the first side; a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a 2 dimensional electron gas (2DEG) conductive channel; a first gate layer on the second side of barrier layer structure and a second gate layer on the second side of barrier layer structure, the first gate layer and the second gate layer latitudinally offset from each other along a direction of the conductive channel; a mesa isolation structure between the first gate layer and the second gate layer, the mesa isolation structure including sidewalls latitudinally offset from each of the first gate layer and the second gate layer, the mesa isolation structure extending from the second side of the barrier layer through an interior of the barrier layer structure, and the mesa isolation structure formed with a dielectric material deposited within the mesa isolation structure; and a dielectric region on the mesa isolation structure, the dielectric region extending from the first gate layer to the second gate layer.

In another nonlimiting illustrative embodiment, a method of forming an integrated circuit (IC) including a mesa isolation structure in a high electron mobility transistor (HEMT) structure comprising: epitaxially growing a carrier channel layer structure on a semiconductor substrate, the carrier channel layer structure including a first side oriented towards the substrate and a second side oriented opposite the first side; epitaxially growing a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a 2 dimensional electron gas (2DEG) conductive channel; using a photolithographic process to form a first gate layer on the second side of barrier layer structure and a second gate layer on the second side of barrier layer structure, the first gate layer and the second gate layer latitudinally offset from each other along a direction of the conductive channel; etching a mesa trench to form sidewalls of a mesa isolation structure, the mesa trench located between the first gate layer and the second gate layer, the mesa trench including sidewalls latitudinally offset from each of the first gate layer and the second gate layer, and the mesa trench extending from the second side of the barrier layer through an interior of the barrier layer structure; forming a mesa isolation structure within the sidewalls of the mesa trench, the mesa isolation structure including a dielectric material deposited within the mesa trench; forming a dielectric region on the mesa isolation structure, the dielectric region extending from the first gate layer to the second gate layer; and patterning a gate metal line which electrically connects the first gate layer and the second gate layer, the gate metal line formed on the dielectric region.

In another nonlimiting illustrative embodiment, a high electron mobility transistor (HEMT) integrated circuit (IC) structure comprising: a carrier channel layer structure epitaxially grown on a semiconductor substrate, the carrier channel layer structure including a first side oriented towards the substrate and a second side oriented opposite the first side; a barrier layer structure epitaxially grown on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a conductive channel; a first gate layer formed on the second side of barrier layer structure using a photolithographic process and a second gate layer formed on the second side of barrier layer structure using a photolithographic process, the first gate layer and the second gate layer latitudinally offset from each other along a direction of the conductive channel; a mesa trench etched to form sidewalls of a mesa isolation structure, the mesa trench located between the first gate layer and the second gate layer, the mesa trench including sidewalls latitudinally offset from each of the first gate layer and the second gate layer, and the mesa trench extending from the second side of the barrier layer through an interior of the barrier layer structure; a mesa isolation structure formed within the sidewalls of the mesa trench, the mesa isolation structure including a dielectric material deposited within the mesa trench; a dielectric region formed on the mesa isolation structure, the dielectric region extending from the first gate layer to the second gate layer; and a patterned gate metal electrically connecting the first gate layer and the second gate layer, the gate metal line formed on the dielectric region.

In another nonlimiting illustrative embodiment, a method of forming an integrated circuit or wafer die including a plurality of high electron mobility transistor (HEMT) structures in an integrated circuit (IC) or semiconductor die, the method comprising: forming a carrier channel layer structure on a semiconductor substrate, the carrier channel layer structure including a first side oriented towards the substrate and a second side oriented opposite the first side; forming a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a conductive channel; and forming a plurality of HEMT transistor structures on the barrier layer structure, each HEMT transistor structure comprising: a first gate layer on the second side of barrier layer structure and a second gate layers on the second side of barrier layer structure, each of the first gate layer and the second gate layer latitudinally offset from each other along a direction of the conductive channel; forming a mesa isolation structure located between the first gate layer and the second gate layer, the mesa isolation structure including sidewalls latitudinally offset from each of the first gate layer and the second gate layer, the mesa isolation structure extending from the second side of the barrier layer through an interior of the barrier layer structure, and the mesa isolation structure formed with a dielectric material; and forming a dielectric region on the mesa isolation structure, the dielectric region extending from the first gate layer to the second gate layer.

In another nonlimiting illustrative embodiment, an integrated circuit (IC) or wafer die semiconductor structure comprising: a carrier channel layer structure on a semiconductor substrate, the carrier channel layer structure including a first side oriented towards the substrate and a second side oriented opposite the first side; a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a conductive channel; a plurality of first gate layers on the second side of barrier layer structure and a plurality of second gate layers on the second side of barrier layer structure, the each first gate layer and each second gate layer latitudinally offset from each other along a direction of the conductive channel; a mesa isolation structure between each of the first gate layer and the second gate layer, the mesa isolation structure including sidewalls latitudinally offset from each of the first gate layer and the second gate layer, the mesa isolation structure extending from the second side of the barrier layer an interior of the barrier layer structure, and the mesa isolation structure formed with a dielectric material; and a dielectric region on the mesa isolation structure, the dielectric region extending from each of the first gate layers to each of the second gate layers.

In another nonlimiting illustrative embodiment, a method of forming an integrated circuit (IC) including a mesa isolation structure in a high electron mobility transistor (HEMT) structure comprising: epitaxially growing a carrier channel layer structure on a semiconductor substrate, the carrier channel layer structure including a first side oriented towards the substrate and a second side oriented opposite the first side; epitaxially growing a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a conductive channel; using a photolithographic process to form a plurality of first gate layers on the second side of barrier layer structure and a plurality of second gate layers on the second side of barrier layer structure, each of the first gate layers and the second gate layers latitudinally offset from each other along a direction of the conductive channel; etching a plurality of mesa trenches, each of the mesa trench forming sidewalls of a mesa isolation structure, each of the mesa trenches located between each of the first gate layers and each of the second gate layers, each of the mesa trenches including sidewalls latitudinally offset from each of the first gate layers and the second gate layers, and each of the mesa trenches extending from the second side of the barrier layer through an interior of the barrier layer structure; forming a plurality of mesa isolation structures, each mesa isolation structure formed within the sidewalls of each of the mesa trenches and each of the mesa isolation structures including a dielectric material deposited within the mesa trench; forming a dielectric region on each of the mesa isolation structures, the dielectric region extending from each of the first gate layers to each of the second gate layers; and patterning a plurality of gate metal lines which electrically connect each of the first gate layers to a respective each of the second gate layers, each gate metal line formed on the dielectric region.

In another nonlimiting illustrative embodiment, a method of forming a semiconductor transistor structure comprising: forming an active area in a semiconductor substrate, the active area including one or more transistor regions having gate, source and drain regions, and the active area comprising: forming a carrier channel layer structure on a semiconductor substrate, the carrier channel layer structure including a first side oriented towards the substrate and a second side oriented opposite the first side; forming a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a conductive channel; forming a first gate layer on the second side of barrier layer structure and a second gate layer on the second side of barrier layer structure, the first gate layer and the second gate layer latitudinally offset from each other along a direction of the conductive channel; and forming a mesa isolation structure located between the first gate layer and the second gate layer, the mesa isolation structure including sidewalls latitudinally offset from each of the first gate layer and the second gate layer, the mesa isolation structure extending from the second side of the barrier layer through an interior of the barrier layer structure, and the mesa isolation structure formed with a dielectric material; and forming a dielectric region on the mesa isolation structure, the dielectric region extending from the first gate layer to the second gate layer; and forming one or more isolation regions laterally adjacent to the active area.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor transistor structure comprising:
forming a carrier channel layer structure on a semiconductor substrate, the carrier channel layer structure including a first side oriented towards the substrate and a second side oriented opposite the first side;
forming a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a 2 dimensional electron gas (2DEG) conductive channel;
forming a first gate layer on the second side of barrier layer structure and a second gate layer on the second side of barrier layer structure, the first gate layer and the second gate layer latitudinally offset from each other along a direction of the conductive channel;
forming a mesa isolation structure located between the first gate layer and the second gate layer, the mesa isolation structure including sidewalls latitudinally offset from each of the first gate layer and the second gate layer, the mesa isolation structure extending from the second side of the barrier layer through at least an interior of the barrier layer structure, and the mesa isolation structure formed with a dielectric material; and
forming a dielectric region on the mesa isolation structure, the dielectric region extending from the first gate layer to the second gate layer.

2. The method of claim 1, wherein forming the mesa isolation structure further comprises:
etching a mesa trench to form the sidewalls of the mesa isolation structure, the mesa trench extending from the second side of the barrier layer through at least the interior of the barrier layer structure.

3. The method of claim 1, wherein forming the mesa isolation structure further comprises:
etching a mesa trench to form the sidewalls; and
forming an isolation (ISO) implant layer or dielectric trench layer within the etched mesa trench, the ISO implant layer including an implantation of ions and the dielectric trench layer including depositing a dielectric layer after etching the mesa trench, the ions and dielectric layer distributed along one or both sidewalls of the mesa trench and along a bottom surface of the mesa trench, the bottom surface of the mesa trench connecting the sidewalls of the mesa trench.

4. The method of claim 1, further comprising:
forming an isolation (ISO) implant layer including an implantation of ions in a mesa trench region, prior to etching the mesa trench; and
etching the mesa trench to form the sidewalls,
wherein a resulting ISO implant layer includes ions distributed along one or both sidewalls of the mesa trench and along a bottom surface of the mesa trench, the bottom surface of the mesa trench connecting the sidewalls of the mesa trench.

5. The method of claim 1, further comprising:
forming the mesa isolation structure to have a top shape and a bottom shape including one of a square, rectangular, and polygon, where a top of the mesa isolation structure is proximate the first and second gate layers.

6. The method of claim 1, further comprising:
forming the mesa isolation structure to have tapered sidewalls, the tapered sidewalls formed such that a top width of the mesa isolation structure is greater than a bottom width of the mesa isolation structure, the top width of the mesa isolation structure proximate the first and second gate layers and the bottom width of the mesa isolation structure opposite the top width.

7. The method of claim 1, wherein the mesa isolation structure is formed to extend from the second side of the barrier layer through the interior of the barrier layer structure and extend through at least a portion of an interior of the carrier channel layer.

8. The method of claim 1, wherein the mesa isolation structure has a trapezoidal or reverse trapezoidal shape.

9. The method of claim 1, further comprising:
forming a common gate metal structure on the dielectric structure, the common gate metal structure electrically connecting the first gate layer and the second gate layer.

10. A semiconductor device comprising:
a carrier channel layer structure on a semiconductor substrate, the carrier channel layer structure including a first side oriented towards the substrate and a second side oriented opposite the first side;
a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a 2 dimensional electron gas (2DEG) conductive channel;
a first gate layer on the second side of barrier layer structure and a second gate layer on the second side of barrier layer structure, the first gate layer and the second gate layer latitudinally offset from each other along a direction of the conductive channel;
a mesa isolation structure between the first gate layer and the second gate layer, the mesa isolation structure including sidewalls latitudinally offset from each of the first gate layer and the second gate layer, the mesa isolation structure extending from the second side of the barrier layer through an interior of the barrier layer structure, and the mesa isolation structure formed with a dielectric material; and
a dielectric region on the mesa isolation structure, the dielectric region extending from the first gate layer to the second gate layer.

11. The device of claim 10, wherein mesa isolation structure further comprises:
a mesa trench etched to form the sidewalls of the mesa isolation structure, the mesa trench extending from the second side of the barrier layer through the interior of the barrier layer structure.

12. The device of claim 10, further comprising:
an isolation (ISO) implant layer or dielectric trench layer, the ISO implant layer and dielectric trench layer distributed along one or both sidewalls of a mesa trench and along a bottom surface of the mesa trench, the bottom surface of the mesa trench connecting the sidewalls of the mesa trench.

13. The device of claim 10, wherein the mesa isolation structure has a top shape and a bottom shape including one of a square, rectangular, and polygon, where a top of the mesa isolation structure is proximate the first and second gate layers.

14. The device of claim 10, wherein the mesa isolation structure has tapered sidewalls, the tapered sidewalls having a top width of the mesa isolation structure that is greater than a bottom width of the mesa isolation structure, the top width of the mesa isolation structure proximate the first and second gate layers and the bottom width of the mesa isolation structure opposite the top width.

15. The device of claim 10, wherein the mesa isolation structure extends from the second side of the barrier layer through the interior of the barrier layer structure and extend through at least a portion of an interior of the carrier channel layer.

16. The device of claim 10, wherein the mesa isolation structure has a trapezoidal or reverse trapezoidal shape.

17. The device of claim 10, further comprising:
a common gate metal structure formed on the dielectric structure, the common gate metal structure electrically connecting the first gate layer and the second gate layer.

18. A method of forming an integrated circuit (IC) including a mesa isolation structure a high electron mobility transistor (HEMT) structure comprising:
epitaxially growing a carrier channel layer structure on a semiconductor substrate, the carrier channel layer structure including a first side oriented towards the substrate and a second side oriented opposite the first side;
epitaxially growing a barrier layer structure on the carrier channel layer structure, the barrier layer structure including a first side oriented towards the carrier channel layer structure and a second side oriented opposite the first side the barrier layer structure, and the carrier channel layer structure and the barrier layer structure providing a heterojunction interface including a 2 dimensional electron gas (2DEG) conductive channel;
using a photolithographic process to form a first gate layer on the second side of barrier layer structure and a second gate layer on the second side of barrier layer structure, the first gate layer and the second gate layer latitudinally offset from each other along a direction of the conductive channel;
etching a mesa trench to form sidewalls of a mesa isolation structure, the mesa trench located between the first gate layer and the second gate layer, the mesa trench including sidewalls latitudinally offset from each of the first gate layer and the second gate layer, and the mesa trench extending from the second side of the barrier layer through an interior of the barrier layer structure;
forming a mesa isolation structure within the sidewalls of the mesa trench, the mesa isolation structure including a dielectric material deposited within the mesa trench;
forming a dielectric region on the mesa isolation structure, the dielectric region extending from the first gate layer to the second gate layer; and
patterning a gate metal line which electrically connects the first gate layer and the second gate layer, the gate metal line formed on the dielectric region.

19. The method of claim 18, further comprising:
forming an isolation (ISO) implementation region or a dielectric trench layer,
wherein the ISO implementation region includes an implantation of ions distributed along one or both sidewalls of the mesa trench and along a bottom surface of the mesa trench, the bottom surface of the mesa trench connecting the sidewalls of the mesa trench; and
wherein the dielectric trench layer is distributed along one or both sidewalls of the mesa trench and along a bottom surface of the mesa trench, the bottom surface of the mesa trench connecting the sidewalls of the mesa trench.

20. The method of claim 18, wherein the carrier channel layer structure is GaN, the barrier layer structure is AlGaN, and the method further comprises:
forming a drain metal structure on the barrier layer structure; and
forming a source metal structure on the barrier layer structure,
wherein the source metal structure and the drain metal structure are aligned substantially orthogonal to the gate metal line formed on the dielectric region.
